(19) United States
(12) Patent Application Publication
(10) Pub. No.: US 2024/0088152 A1
(43) Pub. Date: Mar. 14, 2024

(54) SEMICONDUCTOR DEVICE

(71) Applicant: Kioxia Corporation, Tokyo (JP)

(72) Inventors: Tomoaki SHINO, Kamakura (JP); Mitsuhiro NOGUCHI, Yokohama (JP); Takayuki TOBA, Ota (JP)

(73) Assignee: Kioxia Corporation, Tokyo (JP)

(21) Appl. No.: 18/362,316

(22) Filed: Jul. 31, 2023

(30) Foreign Application Priority Data
Sep. 9, 2022 (JP) 2022-143771

(51) Int. Cl. H01L 27/092; G11C 16/04; G11C 16/06; H01L 21/265; H01L 29/78; H10B 41/27; H10B 41/35; H10B 41/41

(52) U.S. Cl. CPC H01L 27/0922; G11C 16/0483; G11C 16/06; H01L 21/26586; H01L 27/0928; H01L 29/7833; H10B 41/27; H10B 41/35; H10B 41/41

(57) ABSTRACT

A semiconductor device of an embodiment includes N-wells and P-wells extending in a first direction and alternately arranged in a second direction orthogonal to the first direction; and a dummy gate formed above the N-wells and the P-wells so as to extend across at least one boundary between an N-well and a P-well that are adjacent to each other, the dummy gate being not connected to a wire, in which the dummy gate is formed in a region other than an end portion in the first direction of, among the N-wells and the P-wells, a well that has a width smaller than a predetermined threshold in the second direction.

### CROSS-REFERENCE TO RELATED APPLICATION

This application is based upon and claims the benefit of priority from the prior Japanese Patent Application No. 2022-143771 filed in Japan on Sep. 9, 2022; the entire contents of which are incorporated herein by reference.

### FIELD

Embodiments described herein relate generally to a semiconductor device.

### BACKGROUND

In recent years, a NAND memory with a three-dimensional configuration has been in widespread use.

Such a NAND memory includes a CMOS circuit for driving memory cells.

### BRIEF DESCRIPTION OF THE DRAWINGS

FIG. 1 is a block diagram illustrating a configuration example of a memory system;

FIG. 2 is a block diagram illustrating an example of a nonvolatile memory 2 in FIG. 1;

FIG. 3 is a diagram illustrating a configuration example of a block of a memory cell array 23 with a three-dimensional structure;

FIG. 4 is a partial cross-sectional view of a region of a semiconductor storage device according to an embodiment;

FIG. 5 is a plan view illustrating configurations of well regions in a transistor formation region provided in a peripheral circuit region;

FIG. 6 is a plan view illustrating a planar shape of a comparative example of a FET (field-effect transistor) formed in each well region of FIG. 5;

FIG. 7 is an explanatory view for illustrating generation of arcing due to an electron shading effect;

FIG. 8 is an explanatory view for illustrating generation of arcing due to the electron shading effect;

FIG. 9 is a plan view illustrating a planar shape of a FET (field-effect transistor) formed in each well region of FIG. 5;

FIG. 10 is a schematic cross-sectional view illustrating an example of a cross-sectional structure cut along line A-A′ in FIG. 9;

FIG. 11 is a schematic cross-sectional view illustrating an example of a cross-sectional structure cut along line B-B′ in FIG. 9;

FIG. 12 is a schematic cross-sectional view illustrating an example of a cross-sectional structure cut along line C-C′ in FIG. 9;

FIG. 13A is a step view illustrating an ion implantation step;

FIG. 13B is a step view illustrating an ion implantation step;

FIG. 13C is a step view illustrating an ion implantation step;

FIG. 14A is a step view illustrating an ion implantation step;

FIG. 14B is a step view illustrating an ion implantation step;

FIG. 14C is a step view illustrating an ion implantation step;

FIG. 15A is a step view illustrating an ion implantation step;

FIG. 15B is a step view illustrating an ion implantation step;

FIG. 15C is a step view illustrating an ion implantation step;

FIG. 16A is a step view illustrating an ion implantation step;

FIG. 16B is a step view illustrating an ion implantation step;

FIG. 16C is a step view illustrating an ion implantation step;

FIG. 17A is a step view illustrating an ion implantation step;

FIG. 17B is a step view illustrating an ion implantation step;

FIG. 17C is a step view illustrating an ion implantation step;

FIG. 18A is a step view illustrating an ion implantation step;

FIG. 18B is a step view illustrating an ion implantation step;

FIG. 18C is a step view illustrating an ion implantation step;

FIG. 19A is a step view illustrating an ion implantation step;

FIG. 19B is a step view illustrating an ion implantation step;

FIG. 19C is a step view illustrating an ion implantation step;

FIG. 20 is a plan view illustrating an example in which a P-well Pw1 is in contact with a P-well Pw3 on one side in a y-direction;

FIG. 21 is a plan view illustrating a second embodiment; and

FIG. 22 is a plan view illustrating a third embodiment.

### DETAILED DESCRIPTION

A semiconductor device of an embodiment includes N-wells and P-wells extending in a first direction and alternately arranged in a second direction orthogonal to the first direction; and a dummy gate formed above the N-wells and the P-wells so as to extend across at least one boundary between an N-well and a P-well that are adjacent to each other, the dummy gate being not connected to a wire, in which the dummy gate is formed in a region other than an end portion in the first direction of, among the N-wells and the P-wells, a well that has a width smaller than a predetermined threshold in the second direction.

Hereinafter, embodiments of the present invention will be described in detail with reference to the drawings.

### First Embodiment

The present embodiment is directed to, in forming a CMOS circuit with a halo structure by alternately arranging P-wells and N-wells in a predetermined direction, suppress generation of arcing during a halo ion implantation step by partially limiting a region where a dummy gate is formed.

Note that the present embodiment illustrates an example in which the present invention is applied to a transistor region formed in a peripheral circuit that is configured to drive memory cells of a NAND nonvolatile memory, but the present invention is not limited to such an example, and is also applicable to various transistor regions used for not only storage devices but also logic circuits, for example.

### (Configuration of Memory System)

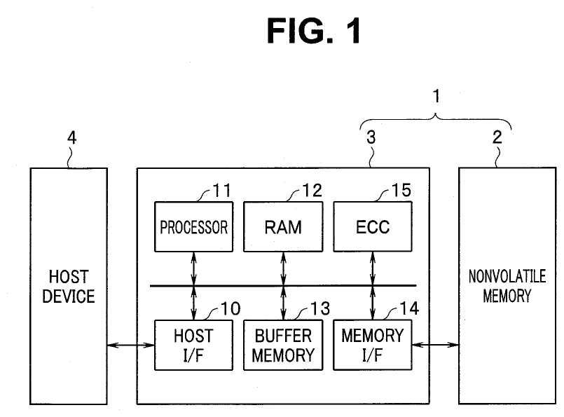

FIG. 1 is a block diagram illustrating a configuration example of a memory system. A memory system 1 of the present embodiment includes a memory controller 3 and a nonvolatile memory 2. Note that the nonvolatile memory 2 may include a plurality of memory chips. The memory system 1 can be connected to a host device 4. The host device 4 is an electronic device, such as a personal computer or a portable terminal.

The memory system 1 may be configured by mounting a plurality of chips to form the memory system 1 on a motherboard on which the host device 4 is mounted. Alternatively, the memory system 1 may be configured as a system LSI (large-scale integrated circuit) or an SoC (system-on-a-chip) implemented with a single module. Examples of the memory system 1 include a memory card, such as an SD card, an SSD (solid-state-drive), and an eMMC (embedded-multi-media-card).

The nonvolatile memory 2 is a NAND memory including a plurality of memory cells, and stores data in a nonvolatile manner. A specific configuration of the nonvolatile memory 2 will be described later.

The memory controller 3 issues an instruction to the nonvolatile memory 2 to write (also referred to as program), read, or erase data, for example, in response to an instruction from the host device 4, for example. The memory controller 3 also manages a memory space of the nonvolatile memory 2. The memory controller 3 includes a host interface (i.e., host I/F) circuit 10, a processor 11, a RAM (random access memory) 12, a buffer memory 13, a memory interface (i.e., memory I/F) circuit 14, and an ECC (error checking and correcting) circuit 15, for example.

The host I/F circuit 10 is connected to the host device 4 via a host bus, and performs an interface process with the host device 4. The host I/F circuit 10 transmits or receives an instruction, an address, and data to/from the host device 4.

The processor 11 includes a CPU (central processing unit), for example. The processor 11 controls the entire operation of the memory controller 3. For example, when the processor 11 receives a write instruction from the host device 4, the processor 11 issues a write instruction to the nonvolatile memory 2 via the memory I/F circuit 14 in accordance with the write instruction from the host device 4. This is also true for reading and erasing. The processor 11 also executes various processes for managing the nonvolatile memory 2, such as wear leveling.

The RAM 12 is used as a work area for the processor 11, and stores firmware data loaded from the nonvolatile memory 2, and various tables created by the processor 11, for example. The RAM 12 includes a DRAM or an SRAM, for example.

The buffer memory 13 temporarily stores data transmitted from the host device 4, and also temporarily stores data transmitted from the nonvolatile memory 2.

The memory I/F circuit 14 is connected to the nonvolatile memory 2 via a bus, and performs an interface process with the nonvolatile memory 2. The memory I/F circuit 14 also transmits or receives an instruction, an address, and data to/from the nonvolatile memory 2.

When data is written, the ECC circuit 15 generates an error correcting code for write data, and adds the error correcting code to the write data, and then transmits the resulting data to the memory I/F circuit 14. When data is read, the ECC circuit 15 performs error detection and/or error correction for the read data using the error correcting code included in the read data. Note that the ECC circuit 15 may be provided in the memory I/F circuit 14.

### (Configuration of Nonvolatile Memory)

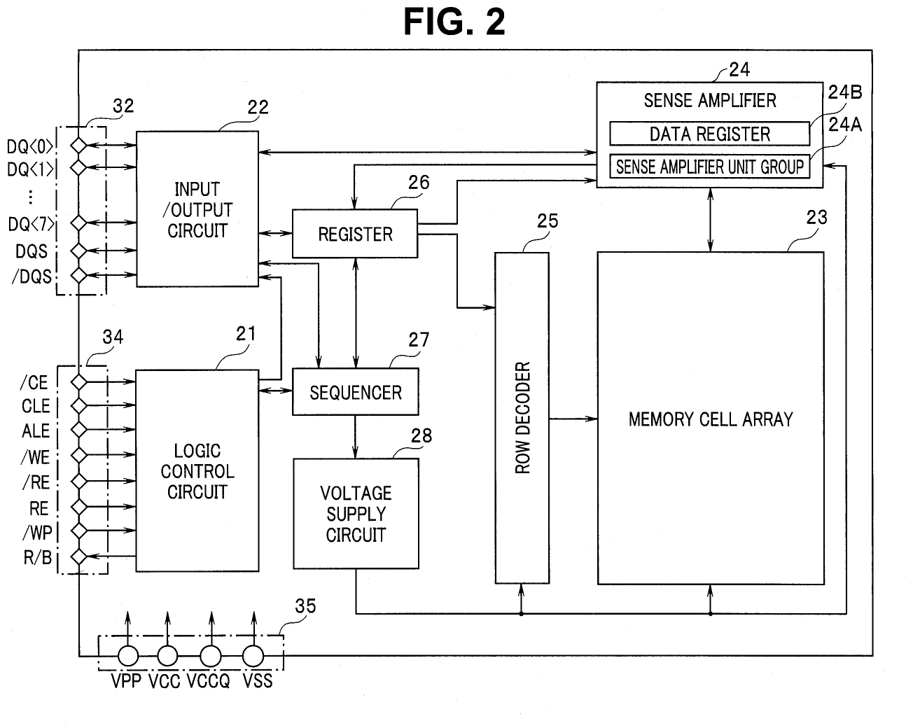

FIG. 2 is a block diagram illustrating an example of the nonvolatile memory 2 in FIG. 1. The nonvolatile memory 2 includes a logic control circuit 21, an input/output circuit 22, a memory cell array 23, a sense amplifier 24, a row decoder 25, a register 26, a sequencer 27, a voltage supply circuit 28, an input/output pad group 32, a logic control pad group 34, and a power supply inputting terminal group 35.

The memory cell array 23 includes a plurality of blocks. Each of the plurality of blocks BLK includes a plurality of memory cell transistors (i.e., memory cells). The memory cell array 23 is provided with a plurality of bit lines, a plurality of word lines, and a source line, for example, for controlling voltages to be applied to the memory cell transistors. A specific configuration of each block BLK will be described later.

The input/output pad group 32 includes a plurality of terminals (i.e., pads) corresponding to signals DQ <7:0> and data strobe signals DQS and/DQS to transmit or receive each signal including data to/from the memory controller 3.

The logic control pad group 34 includes a plurality of terminals (i.e., pads) corresponding to a chip enable signal /CE, a command latch enable signal CLE, an address latch enable signal ALE, a write enable signal /WE, read enable signals RE and /RE, and a write protect signal /WP to transmit or receive each signal to/from the memory controller 3.

The signal /CE enables selection of the nonvolatile memory 2. The signal CLE enables latching of a command transmitted as a signal DQ in a command register. The signal ALE enables latching of an address transmitted as a signal DQ in an address register. The signal WE enables writing. The signal RE enables reading. The signal WP prohibits writing and erasing. A signal R/B indicates whether the nonvolatile memory 2 is in a ready state (i.e., a state in which the nonvolatile memory 2 is able to receive an instruction from outside) or in a busy state (i.e., a state in which the nonvolatile memory 2 is unable to receive an instruction from outside). The memory controller 3 is able to know the state of the nonvolatile memory 2 by receiving the signal R/B.

The power supply inputting terminal group 35 includes a plurality of terminals for inputting power supply voltages VCC, VCCQ, and VPP and a ground voltage VSS to supply various operating power supplies to the nonvolatile memory 2 from outside. The power supply voltage VCC is a circuit power supply voltage that is typically provided as an operating power supply from outside. For example, a voltage of about 3.3 V is inputted as the power supply voltage VCC. As the power supply voltage VCCQ, a voltage of 1.2 V is inputted, for example. The power supply voltage VCCQ is used to transfer signals between the memory controller 3 and the nonvolatile memory 2.

The power supply voltage VPP is a power supply voltage higher than the power supply voltage VCC. For example, a voltage of 12 V is inputted as the power supply voltage VPP. To write data to and erase data from the memory cell array 23, a voltage as high as about 20 V would be necessary. In such a case, it is possible to generate the desired voltage at a high speed and with low power consumption by boosting the power supply voltage VPP of about 12 V rather than by boosting the power supply voltage VCC of about 3.3 V using a boost circuit in the voltage supply circuit 28. The power supply voltage VCC is a power supply that is normally supplied to the nonvolatile memory 2. The power supply voltage VPP is a power supply that is supplied additionally or as appropriate in accordance with the use environment, for example.

The logic control circuit 21 and the input/output circuit 22 are connected to the memory controller 3 via a NAND bus. The input/output circuit 22 transmits or receives signals DQ (e.g., DQ0 to DQ7) to/from the memory controller 3 via the NAND bus.

The logic control circuit 21 receives external control signals (e.g., the chip enable signal /CE, the command latch enable signal CLE, the address latch enable signal ALE, the write enable signal /WE, the read enable signals RE and /RE, and the write protect signal /WP) from the memory controller 3 via the NAND bus. The logic control circuit 21 also transmits the ready/busy signal R/B to the memory controller 3 via the NAND bus.

The input/output circuit 22 transmits or receives the signals DQ <7:0> and the data strobe signals DQS and /DQS to/from the memory controller 3. The input/output circuit 22 transfers commands and addresses in the signals DQ <7:0> to the register 26. In addition, the input/output circuit 22 transmits or receives write data and read data to/from the sense amplifier 24.

The register 26 includes a command register, an address register, and a status register, for example. The command register temporarily stores a command. The address register temporarily stores an address. The status register temporarily stores data necessary for the operation of the nonvolatile memory 2. The register 26 includes an SRAM, for example.

The sequencer 27 receives a command from the register 26, and controls the nonvolatile memory 2 in accordance with a sequence based on the command.

The voltage supply circuit 28 is controlled by the sequencer 27, and receives a power supply voltage from outside of the nonvolatile memory 2. Then, the voltage supply circuit 28 generates a plurality of voltages necessary for a write operation, a read operation, and an erase operation using the power supply voltage.

The row decoder 25 receives a row address from the register 26, and decodes the row address. The row decoder 25 performs an operation of selecting a word line based on the decoded row address. Then, the row decoder 25 transfers a plurality of voltages necessary for a write operation, a read operation, and an erase operation to the selected block.

The sense amplifier 24 receives a column address from the register 26, and decodes the column address. The sense amplifier 24 includes a sense amplifier unit group 24A and a data register 24B. The sense amplifier unit group 24A is connected to each bit line, and selects one of the bit lines based on the decoded column address. When data is read, the sense amplifier unit group 24A detects data read into a bit line from a memory cell transistor, and amplifies the read data. Meanwhile, when data is written, the sense amplifier unit group 24A transfers write data to a bit line.

When data is read, the data register 24B temporarily stores the data detected by the sense amplifier unit group 24A, and serially transfers the data to the input/output circuit 22. Meanwhile, when data is written, the data register 24B temporarily stores data serially transferred from the input/output circuit 22, and transfers the data to the sense amplifier unit group 24A. The data register 24B includes an SRAM, for example.

### (Block Configuration of Memory Cell Array)

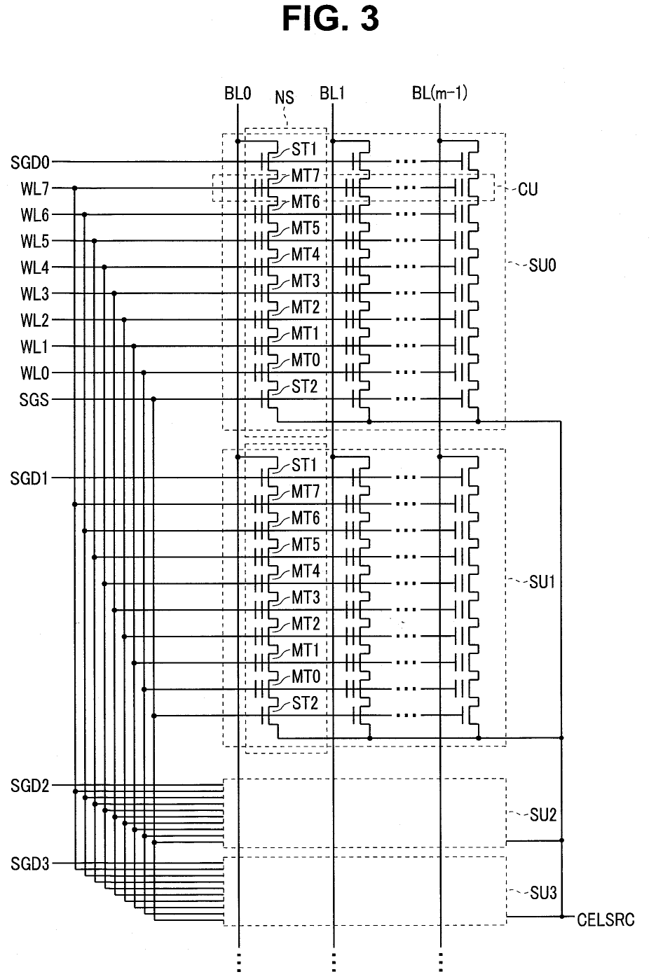

FIG. 3 is a diagram illustrating a configuration example of a block of the memory cell array 23 with a three-dimensional structure. FIG. 3 illustrates one block BLK out of the plurality of blocks forming the memory cell array 23. The other blocks of the memory cell array 23 have a configuration similar to the configuration in FIG. 3.

As illustrated in FIG. 3, the block BLK includes four string units SU0 to SU3 (hereinafter collectively referred to as a string unit SU), for example. Each string unit SU has a NAND string NS including a plurality of memory cell transistors MT (MT0 to MT7) and selection gate transistors ST1 and ST2. Note that the number of memory cell transistors MT included in the NAND string NS is eight in FIG. 3, but more than eight memory cell transistors MT may be included. Each of the selection gate transistors ST1 and ST2, which is indicated as a single transistor on the electric circuit, may be structurally the same as each memory cell transistor. It is also possible to use a plurality of selection gate transistors as each of the selection gate transistors ST1 and ST2. Further, dummy cell transistors may be provided between one of the memory cell transistors MT and the selection gate transistor ST1 and between another one of the memory cell transistors MT and the selection gate transistor ST2.

The memory cell transistors MT are arranged to be connected in series between the selection gate transistors ST1 and ST2. The memory cell transistor MT7 on one end side (i.e., the bit line side) is connected to the selection gate transistor ST1, and the memory cell transistor MT0 on the other end side s (i.e., the source line side) is connected to the selection gate transistor ST2.

Gates of the respective selection gate transistors ST1 in the string units SU0 to SU3 are respectively connected to selection gate lines SGD0 to SGD3 (hereinafter collectively referred to as a selection gate line SGD). Meanwhile, gates of the respective selection gate transistors ST2 in the string units SU0 to SU3 are connected to a common selection gate line SGS. Note that the gates of the plurality of selection gate transistors ST2 in each block BLK may be respectively connected to selection gate lines SGS0 to SGS3 (hereinafter collectively referred to as a selection gate line SGS).

Gates of the memory cell transistors MT0 to MT7 in the same block BLK are respectively connected in common to word lines WL0 to WL7. Namely, the word lines WL0 to WL7 are connected in common to the plurality of string units SU0 to SU3 in the same block BLK, while the selection gate line SGD is provided independently for each of the string units SU0 to SU3 in the same block BLK. Gates of the memory cell transistors MTi in the same row in the block BLK are connected to the same word line WLi.

Each NAND string NS is connected to a corresponding bit line. Thus, each memory cell transistor MT is connected to the bit line via the selection gate transistors ST1 and ST2 and the other memory cell transistors MT included in the NAND string NS. Typically, data in memory cell transistors MT in the same block BLK is erased at a time. Meanwhile, each of data reading and data writing is performed at a time for a plurality of memory cell transistors MT connected in common to a single word line WL provided in a single string unit SU. Such a set including memory cell transistors MT that share the same word line WL in a single string unit SU shall be referred to as a cell unit CU.

Each of a write operation and a read operation for the cell unit CU is executed on a per-page basis. For example, when each cell is a TLC (triple level cell) that can store 3-bit (i.e., 8-value) data, a single cell unit CU can store data for three pages. 3 bits that can be stored in each memory cell transistor MT corresponds to the three pages.

### (Cross-Sectional Structure of Nonvolatile Memory)

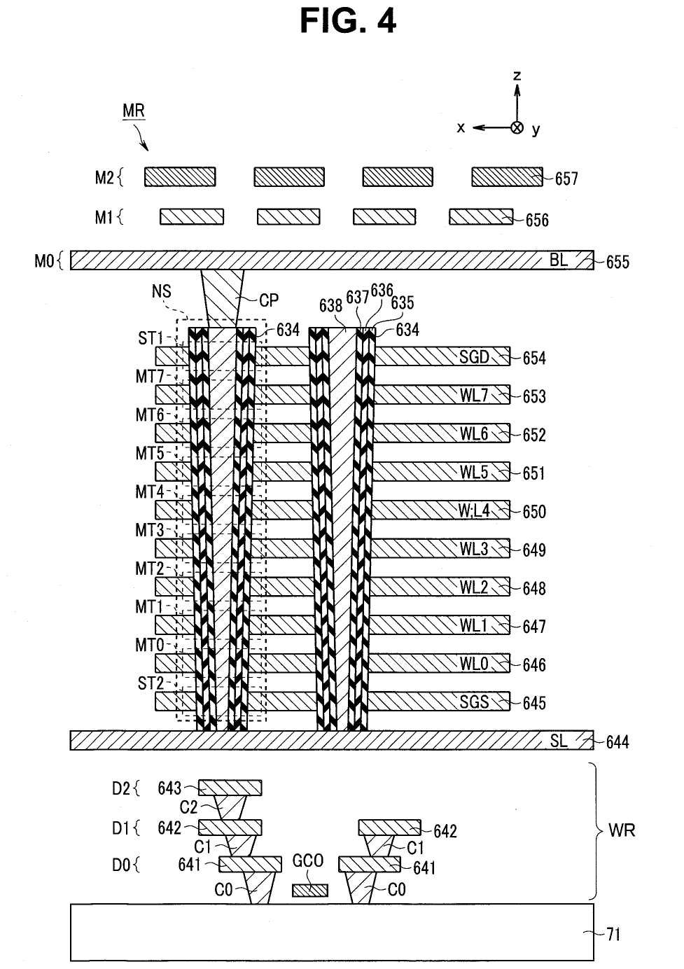

FIG. 4 is a partial cross-sectional view of a region of a semiconductor storage device. FIG. 4 illustrates an example in which a peripheral circuit region corresponding to peripheral circuits, such as the sense amplifier 24 and the row decoder 25, is provided on a semiconductor substrate 71, and a memory region is provided in a layer above the peripheral circuit region. Note that in the following description, two directions that are horizontal to a surface of the semiconductor substrate 71 and are orthogonal to each other shall be referred to as an x-direction and a y-direction, and a direction perpendicular to the surface of the semiconductor substrate 71 shall be referred to as a z-direction.

As illustrated in FIG. 4, in a memory region MR, a nonvolatile memory includes the semiconductor substrate 71, conductors 641 to 657, memory pillars 634, and contacts C0, C1, C2 and CP. Note that in the drawings described below, illustration of each of a P-type or N-type well region formed in an upper surface portion of the semiconductor substrate 71, impurity diffusion regions formed in each well region, and a gate insulating film as well as an element isolation region for isolating the adjacent well regions is omitted.

In the memory region MR, a conductor GC0 is provided on the semiconductor substrate 71 with a gate insulating film (not illustrated) interposed between the conductor GC0 and the semiconductor substrate 71. A plurality of impurity diffusion regions (not illustrated) provided in the semiconductor substrate 71 so as to sandwich the conductor GC0 are respectively provided with contacts C0, for example. The memory cell array 23 is arranged on the semiconductor substrate 71 with a wire layer region WR interposed between the memory cell array 23 and the semiconductor substrate 71.

The conductor 641 to form a wire pattern is provided on each contact C0. For example, the conductor GC0 functions as a gate electrode of a transistor, and the conductor 641 functions as a source electrode or a drain electrode of the transistor.

The contact C1 is provided on each conductor 641, for example. The conductor 642 is provided on each contact C1, for example. The contact C2 is provided on the conductor 642, for example. The conductor 643 is provided on the contact C2, for example.

Each of the wire patterns of the conductors 641, 642, and 643 is provided in the wire layer region WR between the sense amplifier 24 and the memory cell array 23. Hereinafter, wire layers in which the conductors 641, 642, and 643 are provided shall be respectively referred to as wire layers D0, D1, and D2. The wire layers D0, D1, and D2 are provided in a lower layer portion of the nonvolatile memory 2. Note that three wire layers are provided in the wire layer region WR herein, but two or less wire layers, or four or more wire layers may be provided in the wire layer region WR.

The conductor 644 is provided above the conductor 643 with an interlayer dielectric interposed between the conductor 644 and the conductor 643, for example. The conductor 644 is formed in the shape of a plate parallel with an xy plane, for example, and functions as a source line CELSRC. The conductors 645 to 654 are sequentially stacked above the conductor 644, for example, corresponding to each NAND string NS. An interlayer dielectric (not illustrated) is provided between, among the conductors, conductors that are adjacent in the z-direction.

Each of the conductors 645 to 654 is formed in the shape of a plate parallel with the xy plane, for example. For example, the conductor 645 functions as the selection gate line SGS, the conductors 646 to 653 respectively function as the word lines WL0 to WL7, and the conductor 654 functions as the selection gate line SGD.

Each memory pillar 634 is in the shape of a pillar, and penetrates each of the conductors 645 to 654 so as to be in contact with the conductor 644. The memory pillar 634 includes a pillar-shaped semiconductor layer (i.e., a semiconductor pillar) 638 on the center side, and also includes a tunnel insulating film 637 formed on the outer side of the semiconductor layer 638, a charge storage film 636 formed on the outer side of the tunnel insulating film 637, and a block insulating layer 635 formed on the outer side of the charge storage film 636, for example.

For example, a portion where the memory pillar 634 and the conductor 645 cross each other functions as the selection gate transistor ST2. A portion where the memory pillar 634 and each of the conductors 646 to 653 cross each other functions as a memory cell transistor (i.e., a memory cell) MT. A portion where the memory pillar 634 and the conductor 654 cross each other functions as the selection gate transistor ST1.

The conductors 655 are provided in a layer above upper surfaces of the memory pillars 634 with an interlayer dielectric interposed between the conductors 655 and the memory pillars 634. Each conductor 655 is formed in the shape of a line extending in the x-direction, and corresponds to a bit line BL. The plurality of conductors 655 are arranged at intervals in the y-direction (not illustrated). Each conductor 655 is electrically connected to the semiconductor layer 638 in a single corresponding memory pillar 634 of each string unit SU.

Specifically, in each string unit SU, the contact CP is provided on the semiconductor layer 638 in each memory pillar 634, and a single conductor 655 is provided on the contact CP, for example. Note that the present invention is not limited to such a configuration. For example, the semiconductor layer 638 in the memory pillar 634 and the conductor 655 may be connected via a plurality of contacts, wires, and the like.

The conductors 656 are provided in a layer above the layer in which the conductors 655 are provided with an interlayer dielectric interposed between the conductors 656 and the conductors 655. The conductors 657 are provided in a layer above the layer in which the conductors 656 are provided with an interlayer dielectric interposed between the conductors 657 and the conductors 656.

The conductors 656 and 657 correspond to wires for connecting wires provided in the memory cell array 23 to the peripheral circuits provided below the memory cell array 23, for example. The conductors 656 and 657 may be connected via pillar-shaped contacts (not illustrated). Herein, the layer in which the conductors 655 are provided is referred to as a wire layer M0, the layer in which the conductors 656 are provided is referred to as a wire layer M1, and the layer in which the conductors 657 are provided is referred to as a wire layer M2.

As illustrated in FIG. 4, in the semiconductor storage device, the wire layers D0, D1, D2 are formed in the layers below the string unit SU. In addition, the wire layers M0, M1, and M2 are formed in the layers above the string unit SU. The wire layers D0, D1, and D2 are tungsten wires formed using a damascene method, for example.

The wire layer M2 corresponds to aluminum wires formed by anisotropic etching, such as reactive ion etching (RIE). Since the wire layer M2 is thick and has low resistance, basic power supply wires (VCC and VSS) are allocated as the wire layer M2. The wire layer M1 corresponds to copper (Cu) wires formed using the damascene method, for example. Since the Cu wires have high reliability, such as high EM (electromigration) resistance, signal wires that need to reliably transmit data are allocated as the wire layer M1. The wire layer M0 corresponds to Cu wires formed using the damascene method, for example. The wire layer M0 is used as the bit lines BL, and also, some of the basic power supply wires are allocated as the wire layer M0 for the purpose of maintaining a stable power supply. Note that wires other than the basic power supply wires, such as signal wires, also preferably have as low a resistance as possible. Thus, such wires are formed using upper wire layers if possible (for example, the wire layer M2).

### Comparative Example

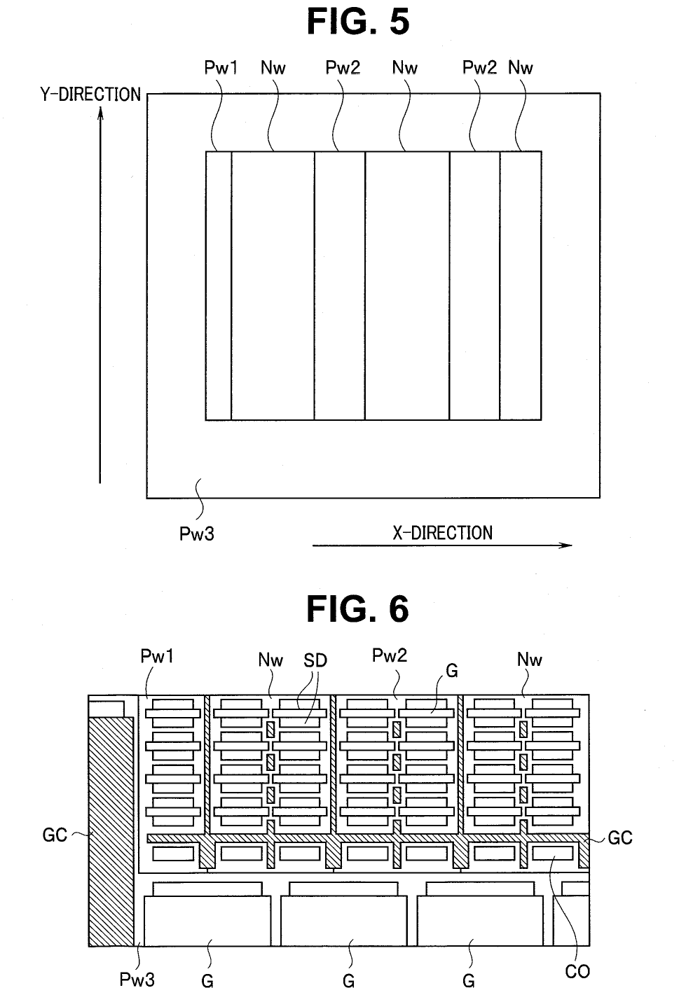

FIG. 5 is a plan view illustrating configurations of well regions in a transistor formation region provided in the peripheral circuit region. FIG. 6 is a plan view illustrating a planar shape of a comparative example of a FET (field-effect transistor) formed in each well region of FIG. 5.

For a semiconductor device, such as a semiconductor memory, a plurality of types of transistors having gate insulating films with different thicknesses are adopted. For example, an HV (high voltage) transistor with a sufficiently thick gate insulating film is adopted as a transistor configured to transfer a high voltage to be applied to the row decoder 25, while an LV (low voltage) transistor with a relatively thin gate insulating film is adopted as a transistor configured to transfer an intermediate voltage to be applied to the sense amplifier 24. Further, a VLV (very low voltage) transistor with an ultrathin gate insulating film is used as a transistor that is required to have high-speed performance in the input/output circuit 22, for example.

As illustrated in FIG. 5, a P-well Pw3 that is a P-type well region is formed around a P-well Pw1 and P-wells Pw2 that are P-type well regions (hereinafter collectively referred to as P-wells Pw unless there is a need to distinguish between the P-wells), and N-wells Nw that are N-type well regions. The P-wells Pw1 and Pw2 and the N-wells Nw extend in the Y-direction that is the first direction. The P-wells Pw1 and Pw2 and the N-wells Nw are alternately formed in the X-direction that is the second direction. Note that the P-wells Pw1 and Pw2 and the N-wells Nw are regions in which VLV transistors are formed, for example.

The P-well Pw1 is a region in which an N channel FET (NFET) is formed that has a thin gate insulating film and to which oblique halo ion implantation is applied. Although each P-well Pw2 has a configuration similar to the configuration of the P-well Pw1, the P-well Pw2 is wider than the P-well Pw1 in the X-direction. Namely, a width of the P-well Pw1 in the X-direction is smaller than a predetermined threshold. As illustrated in FIG. 6, a P-well contact region CO is formed at an end portion of the P-well Pw1 in the Y-direction. A gate G is formed in a shape extending in the X-direction with respect to diffusion layers forming a source S and a drain D, and NFETs are formed in the P-wells Pw1 and Pw2.

Each N-well Nw is a region in which a P channel FET (PFET) is formed that has a thin gate insulating film and to which oblique halo ion implantation is applied.

The P-well Pw3 is a region in which an NFET is formed that has a thick gate insulating film and to which oblique halo ion implantation is not applied. Note that the P-well Pw3 is a region in which LV and HV transistors are formed, for example, and is formed to surround the P-wells Pw1 and Pw2 and the N-wells Nw.

For a boundary between a P-well and a N-well that are adjacent to each other, a constant distance for preventing malfunctions needs to be allocated. If there are many boundaries, arrangement efficiency will be low, and a chip size will increase. Thus, as illustrated in FIG. 5, the P-wells extending in the Y-direction and the N-wells extending in the Y-direction are alternately arranged in the X-direction so that the element arrangement efficiency is improved. Namely, although a CMOS circuit is formed using a pair of a P-well and an N-well, arranging the wells like a P-well-an N-well, an N-well-a P-well, and a P-well-an N-well, . . . can reduce the number of boundaries each existing between a P-well and an N-well that are adjacent to each other. As a result of such a configuration, a well located at an end portion in the X-direction tends to be narrower than the other wells.

Note that a dummy gate GC (indicated by a shaded portion) is formed above the P-wells Pw and the N-wells Nw. The dummy gate GC is provided to maintain flatness of an interlayer film on the dummy gate GC when the interlayer film is polished by CMP (chemical mechanical polishing). No contact is formed on the dummy gate GC, and thus, the dummy gate GC is in a floating state.

### (Arcing)

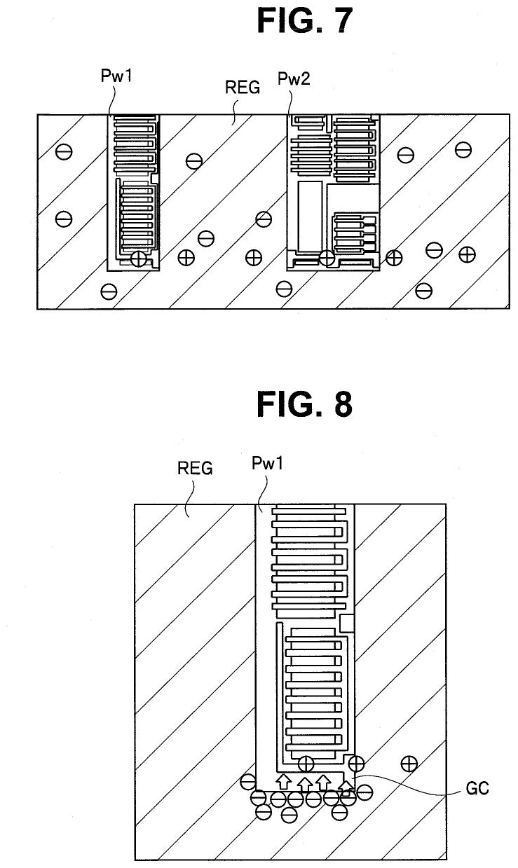

FIGS. 7 and 8 are explanatory views for illustrating generation of arcing due to an electron shading effect. Note that in FIGS. 7 and 8, negative charges are indicated by minus signs, and positive charges are indicated by plus signs.

To improve performance of a transistor, it is necessary to form a thin gate insulating film and use an oblique halo ion implantation technique. FIG. 7 illustrates a view in which resist REG (indicated by a hatched portion) is formed in a region of the N-well Nw, and oblique halo ion implantation is performed in regions of the P-well Pw1 and the P-well Pw2. In the halo ion implantation, positively charged boron is implanted, for example. In such a case, neutralizing electrons for preventing the gate from being positively charged are also implanted. However, the neutralizing electrons also charge a surface of the resist REG. Due to the neutralizing electrons that have charged the resist REG, an electron shading effect occurs by which neutralizing electrons cannot reach open portions in the resist REG.

In particular, the electron shading effect is likely to occur around a region where a width of a well in the X-direction is small and the resist REG is present around the well in three directions, that is, around an end portion of the P-well Pw1 in the Y-direction. In addition, the electron shading effect would become significant when the width of the well is reduced in accordance with miniaturization.

Due to the electron shading effect, neutralizing electrons become difficult to be implanted into the gate G, and positively charged impurities (e.g., boron) are implanted dominantly, whereby the gate G is positively charged up. This increases the possibility of drawing electrons on the surface of the resist REG toward the dummy gate GC and thus inducing arcing in a region where a distance between the resist REG and the dummy gate GC is relatively short as indicated by arrows in FIG. 8. If arcing occurs, surrounding structures would be destroyed by heat, with the result that a semiconductor device that operates normally cannot be provided. Note that the dummy gate GC is formed continuously in a relatively wide range, and thus, arcing also occurs in each place other than the end portion.

### (Countermeasure)

Thus, in the present embodiment, no dummy gate GC is arranged above a STI (shallow trench isolation) region, which is an element isolation region around the P-well contact, in a region where the resist REG is present in a relatively nearby position, that is, around the end portion of the P-well Pw1 in the Y-direction where the resist REG is present around the P-well Pw1 in three directions. Accordingly, since there is no structure to be charged up, it is possible to prevent arcing from being induced. Consequently, a semiconductor device suitable for miniaturization can be provided.

### (Planar Shape of Embodiment)

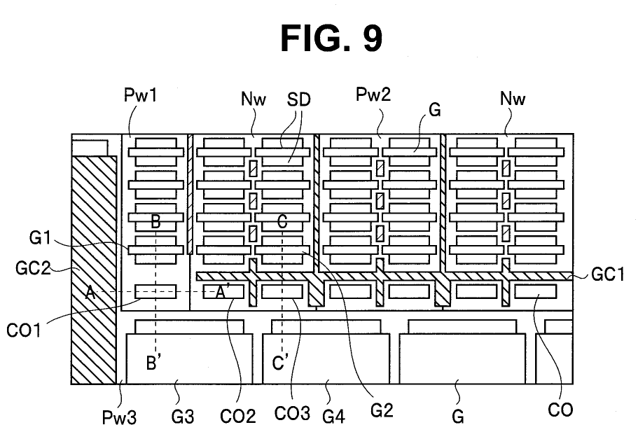

FIG. 9 is a plan view illustrating an example of a planar shape of a FET formed in each well region of FIG. 5. In FIG. 9, components identical to the components in FIG. 6 are denoted by identical reference signs, and overlapped description will be omitted.

As illustrated in FIG. 9, configurations of diffusion layers as a source S and a drain D and a gate G that form the FET are similar to the configurations in FIG. 6, and a configuration of the contact region CO is also similar to the configuration in FIG. 6. In the present embodiment, a planar shape of the dummy gate GC is different from a planar shape of the dummy gate GC of the comparative example in FIG. 6.

Namely, in the present embodiment, no dummy gate GC is arranged above an end portion of the P-well Pw1 in the Y-direction. The dummy gate GC is formed continuously in a relatively wide range, and is formed across at least one boundary between an N-well and a P-well that are adjacent to each other. The dummy gate GC is formed in a region other than the end portion of the P-well Pw1 in the Y-direction. A width of the P-well Pw1 in the X-direction is smaller than a predetermined width, and thus, the end portion of the P-well Pw1 in the Y-direction is likely to be influenced by neutralizing electrons on the resist REG due to the electron shading effect during oblique halo ion implantation. Thus, the dummy gate GC that would be charged up is not formed at the end portion of the P-well Pw1 in the Y-direction that is likely to be charged up during oblique halo ion implantation. Accordingly, generation of arcing can be prevented in the present embodiment.

Note that in FIG. 9, a dummy gate and contact regions at positions corresponding to line A-A′ are respectively indicated by reference signs GC2, CO1, and CO2, gates and a contact region at positions corresponding to line B-B′ are respectively indicated by reference signs G1, G3, and CO1, and gates, a dummy gate, and a contact region at positions corresponding to line C-C′ are respectively indicated by reference signs G2, G4, GC1, and CO3.

### (Cross-Sectional Shape)

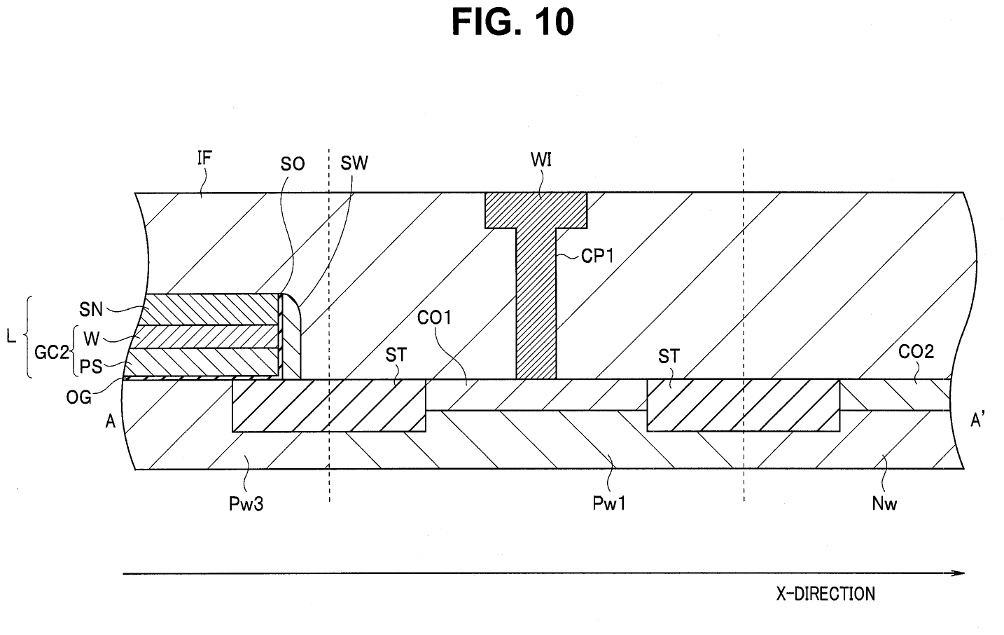

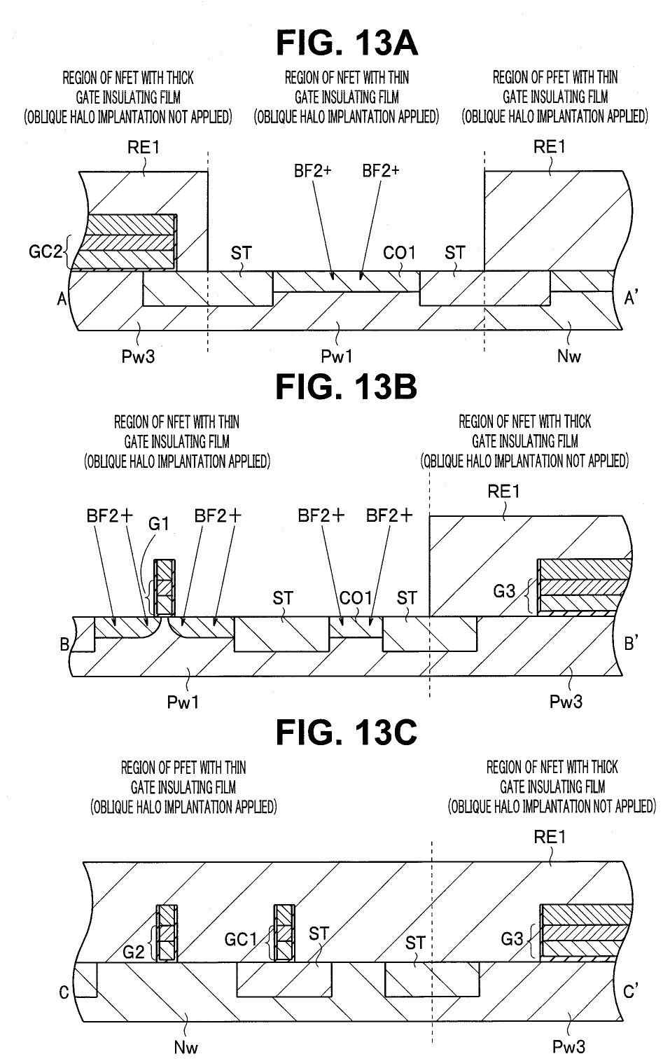

Next, a cross-sectional shape will be described with reference to FIGS. 10 to 12. Note that in each of FIGS. 10 to 12 as well as FIGS. 13A to 13C to FIGS. 19A to 19C described below, a dashed line extending in a longitudinal direction on a sheet surface indicates a boundary between adjacent wells.

FIG. 10 is a schematic cross-sectional view illustrating an example of a cross-sectional structure cut along line A-A′ in FIG. 9. Line A-A′ is a straight line extending in the X-direction and crossing the contact region CO1 at the end portion of the P-well Pw1 in the Y-direction, and includes the P-well Pw1, a part of the N-well Nw on one side and, a part of the dummy gate GC2 on the other side in the X-direction.

The P-well Pw3, the P-well Pw1, and the N-well Nw are formed in the semiconductor substrate 71. Around the surface of the semiconductor substrate 71, STI regions ST each adapted to isolate adjacent wells are formed at a boundary between the P-well Pw3 and the P-well Pw1 and at a boundary between the P-well Pw1 and the N-well Nw.

The contact region CO1 is formed on a substrate surface of the P-well Pw1, and a wire WI is connected to the contact region CO1 via a contact CP1. The contact region CO2 is formed on a substrate surface of the N-well Nw. Note that illustration of the wire WI is omitted in FIG. 9.

A gate oxide film OG is formed on a substrate surface of the P-well Pw3. The dummy gate GC2, which includes an N-type polysilicon film PS and a tungsten film W, and a silicon nitride film SN are stacked on the gate oxide film OG, and an offset spacer SO and a sidewall SW are formed on a side portion of the stack L. Note that an interlayer film IF is formed on the silicon nitride film SN, the offset spacer SO, the sidewall SW, the STI regions ST, and the contact regions CO1 and CO2 up to an upper surface of the wire WI.

As described above, the width of the P-well Pw1 is smaller than the predetermined width. As illustrated in FIG. 10, the end portion of the P-well Pw1 in the Y-direction is provided with the contact region CO1. No dummy gate GC is arranged above the STI region ST at the boundary between the P-well Pw1 and the N-well Nw. Namely, no dummy gate GC is arranged above the end portion of the P-well Pw1 in the Y-direction.

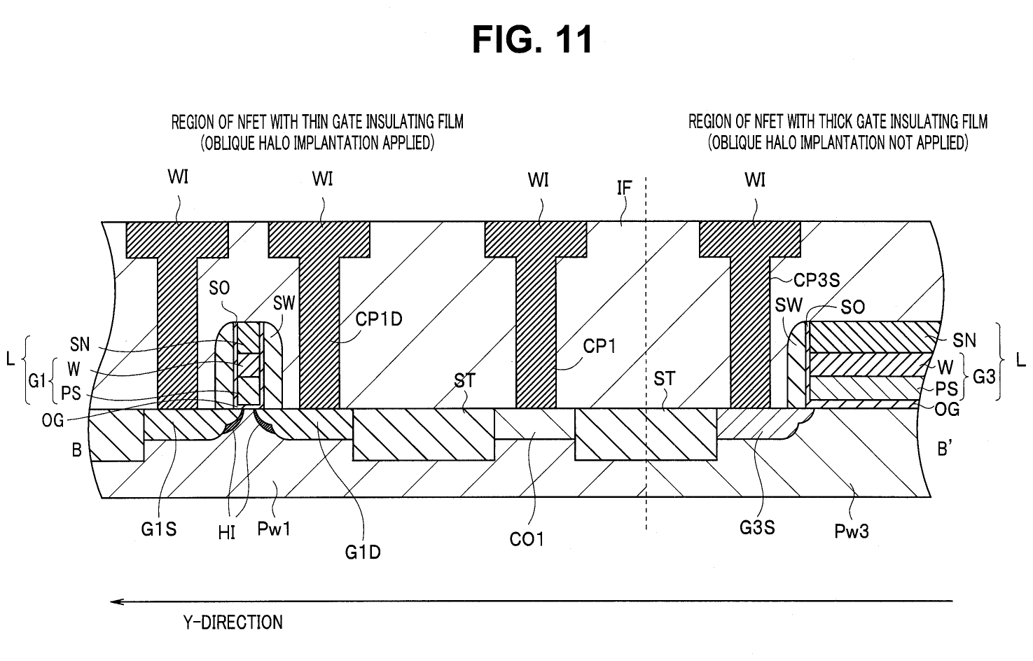

FIG. 11 is a schematic cross-sectional view illustrating an example of a cross-sectional structure cut along line B-B′ in FIG. 9. Line B-B′ is a straight line crossing the contact region CO1 at the end portion of the P-well Pw1 in the Y-direction along the y-direction, and includes the NFET formed in the P-well Pw1 and a part of the gate G3 formed above the P-well Pw3 in the Y-direction of the P-well Pw1.

The P-well Pw1 and the P-well Pw3 are formed in the semiconductor substrate 71. Around the surface of the semiconductor substrate 71, the contact region CO1 is formed at the end portion of the P-well Pw1 in the Y-direction, and STI regions ST each adapted to isolate adjacent wells are formed at a boundary between the contact region CO1 and the P-well Pw3 and at a boundary between the contact region CO1 and a region of the P-well Pw1 in which the NFET is formed.

In the region of the P-well Pw1 in which the NFET is formed, a source G1S of an N⁺-type diffusion layer and a drain G1D of an N⁺-type diffusion layer are formed at a predetermined interval in the Y-direction around the substrate surface. Around a substrate surface of a region of the P-well Pw1 interposed between the N⁺-type diffusion layer (i.e., the source) and the N⁺-type diffusion layer (i.e., the drain), a stack L of a gate G1, which is formed of an N-type polysilicon film PS and a tungsten film W, and a silicon nitride film SN is formed on the gate oxide film OG, and an offset spacer SO and a sidewall SW are formed on each of opposite sides of the stack L in the Y-direction. The source G1S and the drain G1D are respectively connected to wires WI via contacts CP1 and CP1D. Note that diffusion layers HI are formed in regions around a channel between the source G1S and the drain G1D by oblique halo ion implantation.

In the region of the P-well Pw3 in which the NFET is formed, a source GS3 of an N⁺-type diffusion layer and a drain (not illustrated) of an N⁺-type diffusion layer are formed at a predetermined interval in the Y-direction around the substrate surface. Note that oblique halo ion implantation is not applied to the source G3S or the drain formed in the P-well Pw3. Around a substrate surface of a region of the P-well Pw3 interposed between the source G3S and the drain, a stack L of a gate G3, which is formed of an N-type polysilicon film PS and a tungsten film W, and a silicon nitride film SN is formed on the gate oxide film OG, and an offset spacer SO and a sidewall SW are formed on each of opposite sides of the stack L in the Y-direction. The source G3S and the drain are respectively connected to wires WI via a contact CP3S and a contact (not illustrated).

As illustrated in FIG. 11, the end portion of the P-well Pw1 in the Y-direction is provided with the contact region CO1. No dummy gate GC is arranged above an STI region ST at a boundary between the P-well Pw1 and the P-well Pw3. Likewise, no dummy gate GC is arranged above an STI region ST between the contact region CO1 and the drain G1D.

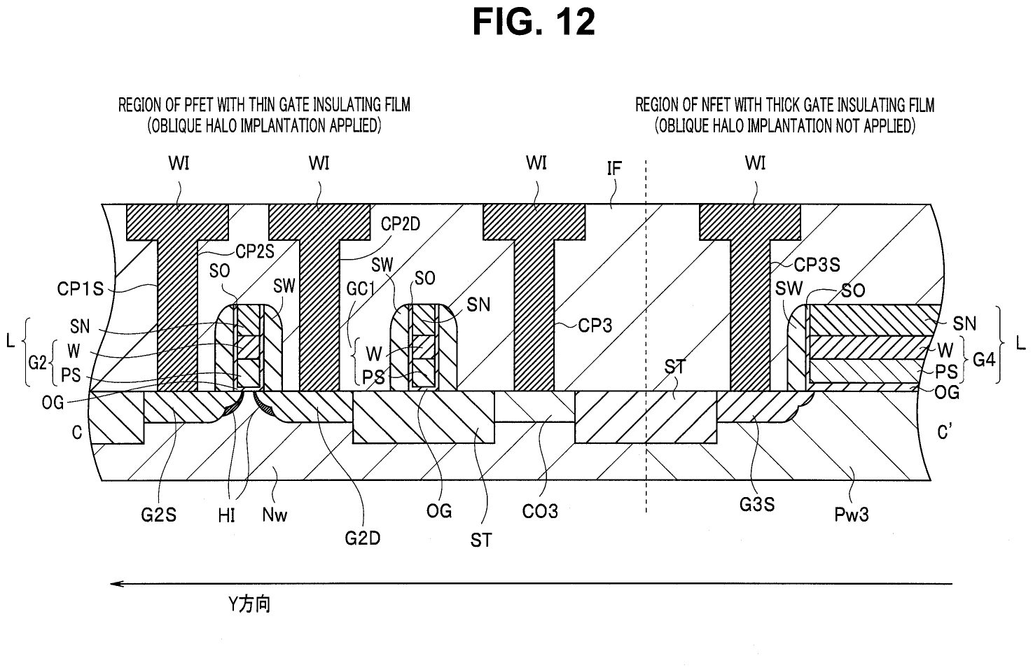

FIG. 12 is a schematic cross-sectional view illustrating an example of a cross-sectional structure cut along line C-C′ in FIG. 9. Line C-C′ is a straight line cutting the N-well Nw in the Y-direction, and includes the PFET formed in the N-well Nw, the dummy gate GC1 formed in the N-well Nw, the contact region CO3 at an end portion of the N-well Nw in the Y-direction, and a part of the gate G4 formed in the P-well Pw3.

The N-well Nw and the P-well Pw3 are formed in the semiconductor substrate 71. Around the surface of the semiconductor substrate 71, the contact region CO3 is formed at the end portion of the N-well Nw in the Y-direction, and STI regions ST each adapted to isolate adjacent wells are formed at a boundary between the contact region CO3 and the P-well Pw3 and at a boundary between the contact region CO3 and a region of the N-well Nw in which the PFET is formed. Note that the contact region CO3 is connected to a wire WI via a contact CP3.

In the region of the N-well Nw in which the PFET is formed, a source G2S of a Pt-type diffusion layer and a drain G2D of a Pt-type diffusion layer are formed at a predetermined interval in the Y-direction around the substrate surface. Around a substrate surface of a region of the N-well Nw interposed between the source G2S and the drain G2D, a stack L of a gate G2, which includes an N-type polysilicon film PS and a tungsten film W, and a silicon nitride film SN is formed on the gate oxide film OG, and an offset spacer SO and a sidewall SW are formed on each of opposite sides of the stack L in the Y-direction. The source G2S and the drain G2D are respectively connected to wires WI via contacts CP2S and CP2D. Note that diffusion layers HI are formed in regions around a channel between the source G2S and the drain G2D by oblique halo ion implantation.

In the region of the P-well Pw3 in which the NFET is formed, a source G3S of an N⁺-type diffusion layer and a drain (not illustrated) of an N⁺-type diffusion layer are formed at a predetermined interval in the Y-direction around the substrate surface. Note that oblique halo ion implantation is not applied to the source G3S or the drain formed in the P-well Pw3. Around a substrate surface of a region of the P-well Pw3 interposed between the source G3S and the drain, a stack L of the gate G4, which includes an N-type polysilicon film PS and a tungsten film W, and a silicon nitride film SN is formed on the gate oxide film OG, and an offset spacer SO and a sidewall SW are formed on each of opposite sides of the stack L in the Y-direction. The source G3S and the drain are respectively connected to wires WI via a contact CP3S and a contact (not illustrated).

Above the STI region ST, a stack of the dummy gate GC1, which includes an N-type polysilicon film PS and a tungsten film W, and a silicon nitride film SN is formed on the gate oxide film OG. Note that an offset spacer SO and a sidewall SW are formed on each of opposite sides of the stack in the Y-direction.

As illustrated in FIG. 12, the end portion of the N-well Nw in the Y-direction is provided with the contact region CO3. No dummy gate GC is arranged above an STI region ST between the contact region CO3 and the source G3S of the P-well Pw3. Meanwhile, the dummy gate GC1 is arranged above the STI region ST between the contact region CO3 and the region in which the PFET is formed. The N-well Nw is formed relatively wide in the X-direction to such an extent that arcing does not occur. Therefore, arcing does not occur even when the dummy gate GC1 is arranged above the STI region ST interposed between the contact region CO3 and the drain G2D. Arranging the dummy gate GC1 can prevent a decrease in the density of the dummy gate GC, and maintain flatness of an interlayer film IF on the dummy gate GC when the interlayer film IF is polished by CMP. Consequently, generation of malfunctions due to short-circuit between wires can be prevented.

### (Halo Ion Implantation Step and LDD Ion Implantation Step)

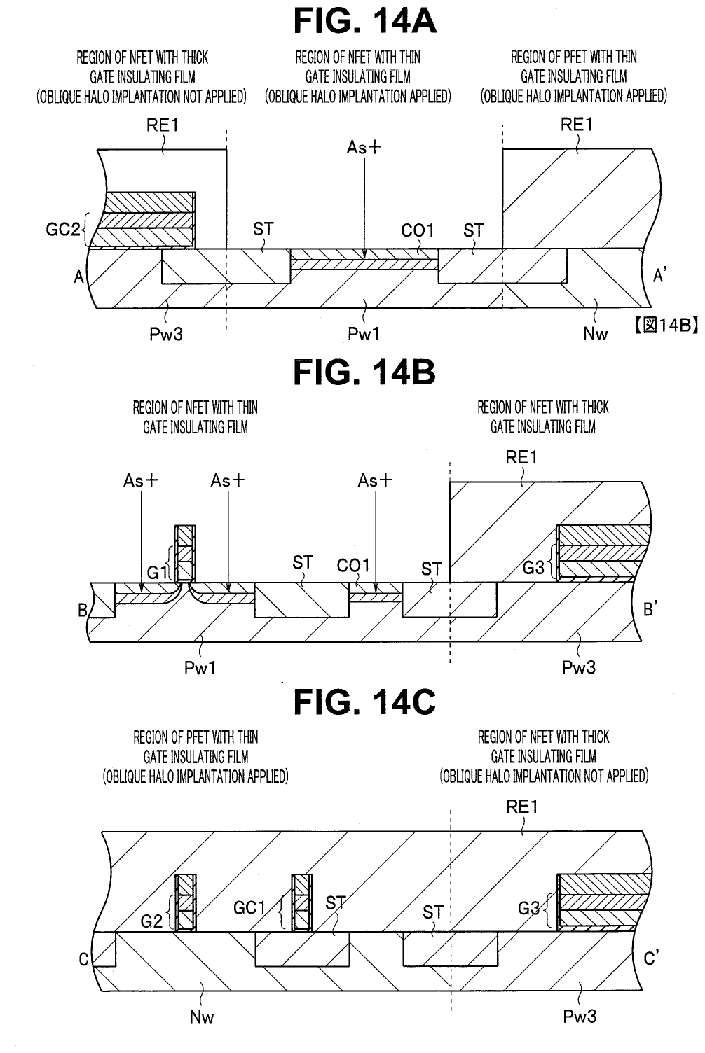

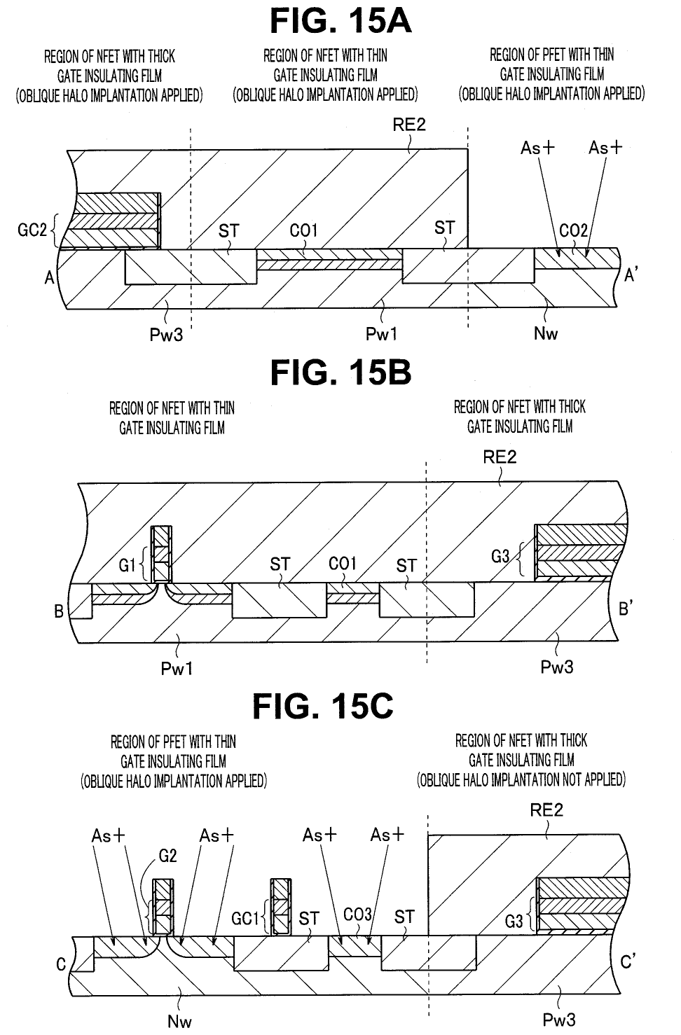

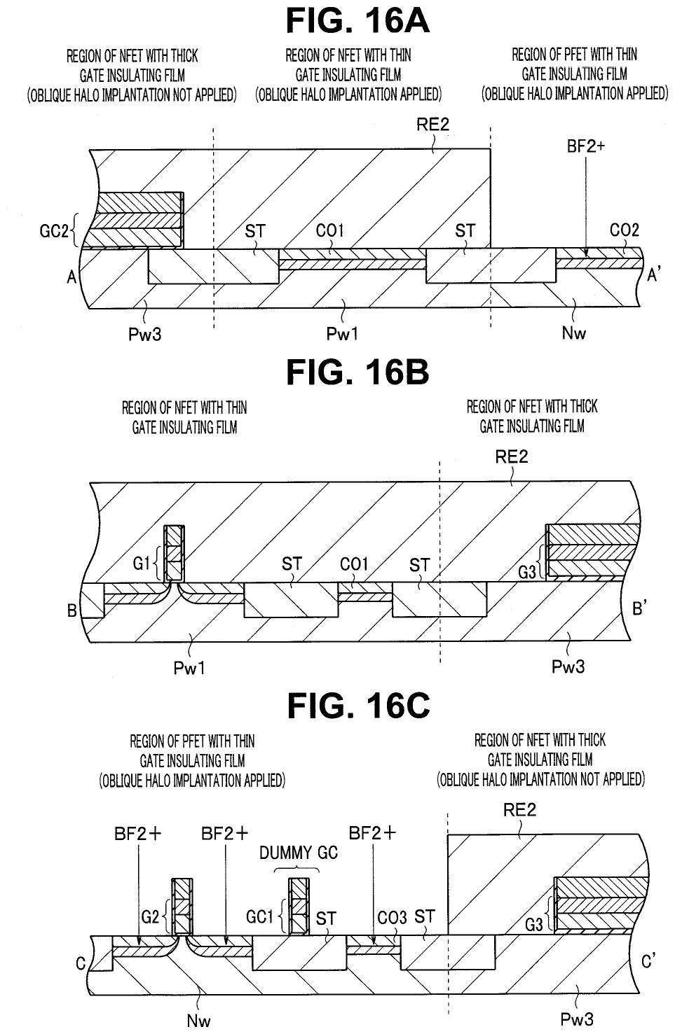

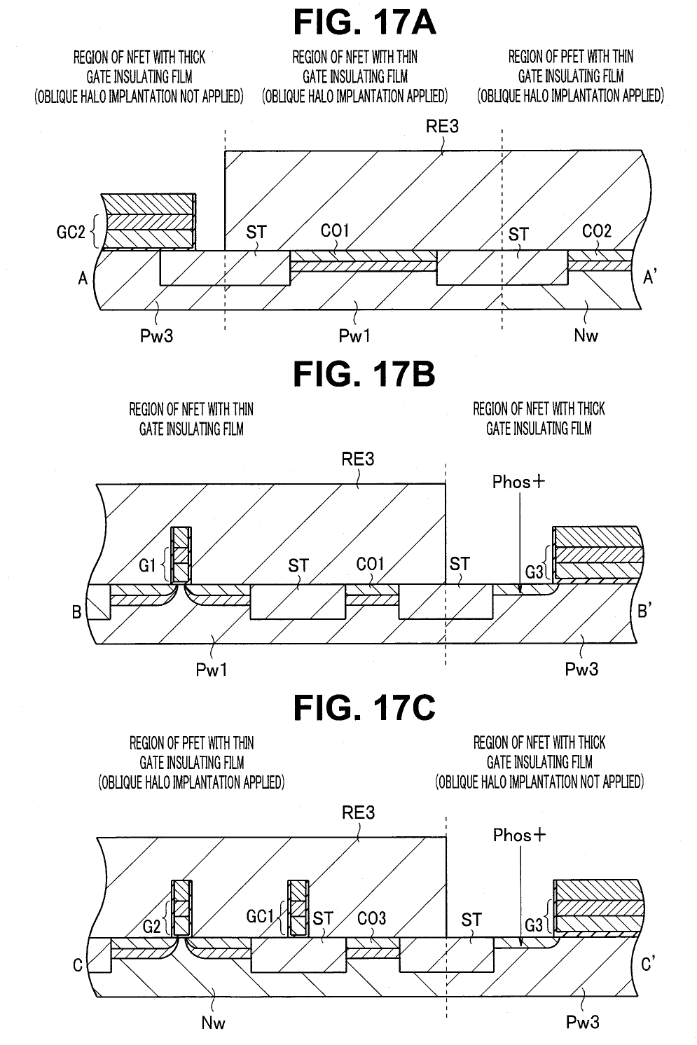

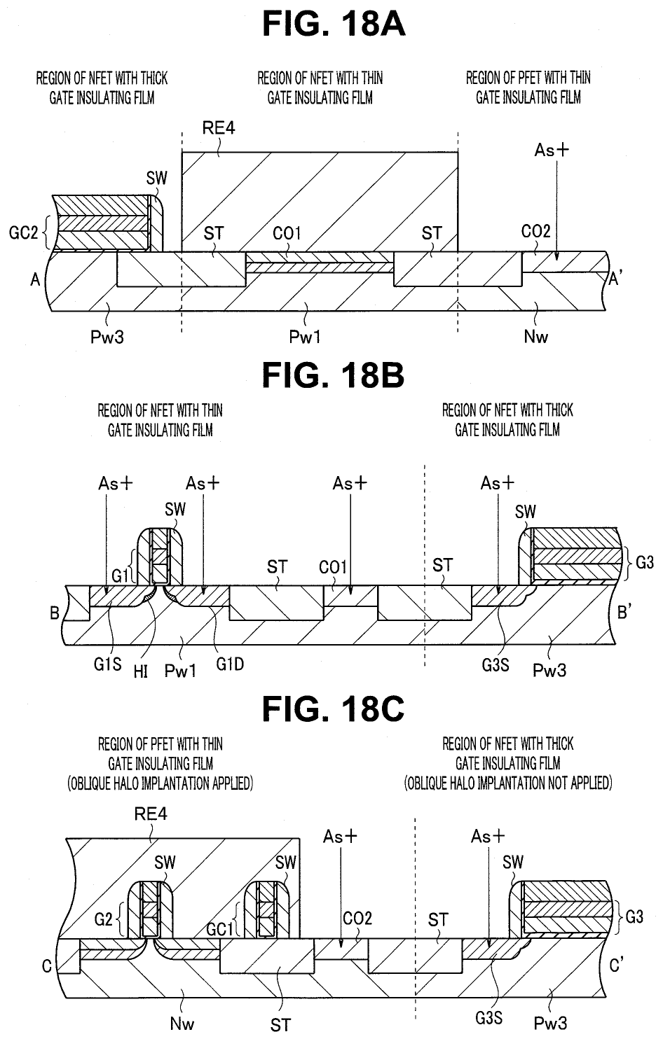

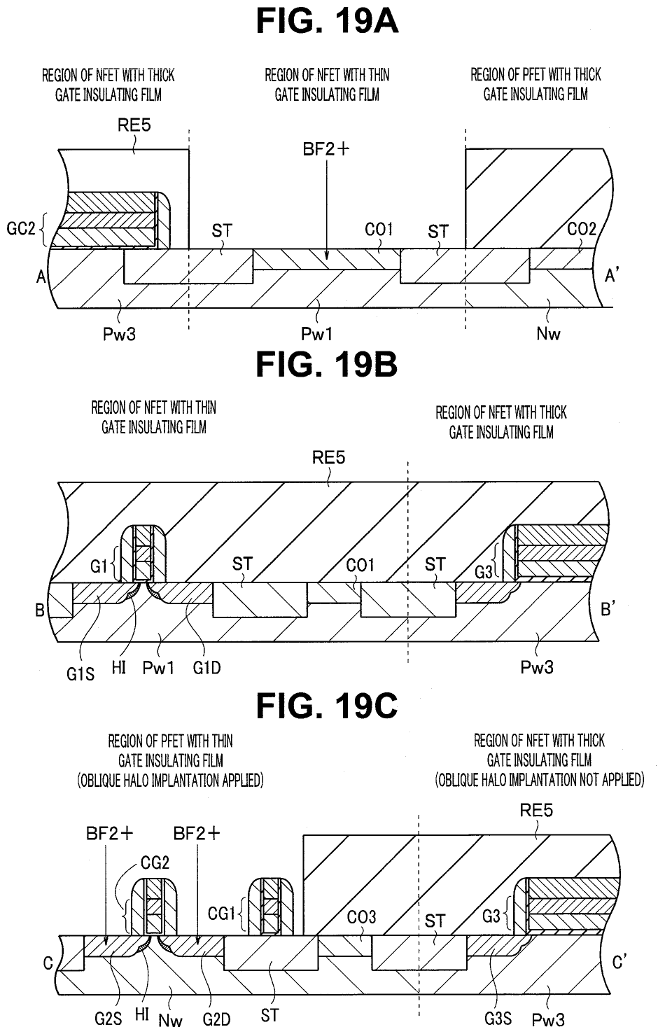

Next, various ion implantation steps will be described with reference to FIGS. 13A to 13C to FIGS. 19A to 19C. FIGS. 13A and 14A to 19A are step views illustrating various ion implantation steps based on cross-sectional structures cut along line A-A′ in FIG. 9. FIGS. 13B and 14B to 19B are step views illustrating various ion implantation steps based on cross-sectional structures cut along line B-B′ in FIG. 9. FIGS. 13C and 14C to 19C are step views illustrating various ion implantation steps based on cross-sectional structures cut along line C-C′ in FIG. 9. FIGS. 13A to 13C and FIGS. 14A to 14C mainly illustrate an ion implantation step for forming NFETs in the P-well Pw1 and the P-well Pw2. FIGS. 15A to 15C and FIGS. 16A to 16C mainly illustrate an ion implantation step for forming PFETs. FIGS. 17A to 17C mainly illustrate an ion implantation step for forming an NFET in the P-well Pw3. FIGS. 18A to 18C mainly illustrate an ion implantation step for forming NFETs in the P-wells Pw1 and Pw2. FIGS. 19A to 19C mainly illustrate an ion implantation step for forming a PFET in the N-well Nw.

FIGS. 13A to 13C mainly illustrate an oblique halo ion implantation step. A state in FIGS. 13A to 13C is a state in which resist RE1 for oblique halo ion implantation is formed after the offset spacer SO is formed.

Namely, the P-well Pw1, the P-wells Pw2, the P-well Pw3, and the N-wells Nw are formed first in the semiconductor substrate 71 using an ion implantation method. The P-wells Pw1 and Pw2 and the N-wells Nw are alternately formed in the X-direction, and then, the P-well Pw3 is formed to surround the P-wells Pw1 and Pw2 and the N-wells Nw.

Next, the STI regions ST are formed on the surface of the semiconductor substrate 71 using an STI method.

Next, the gate oxide film OG is formed on the surfaces of the P-wells Pw1 and Pw2 and the N-wells Nw. The gate oxide film OG is a silicon oxide film, for example, and can be formed using a thermal oxidation method, for example. Next, an N-type polysilicon film PS is formed using a CVD (chemical vapor deposition) method, for example. Next, a tungsten film W is formed on the N-type polysilicon film PS, and further, a silicon nitride film SN is formed using the CVD method.

Next, the stack L of the N-type polysilicon film PS, the tungsten film W, and the silicon nitride film SN is patterned using a photolithography technique and an anisotropic etching technique. Accordingly, patterned gates G (i.e., G1, G2, G3, GC1, and GC2) are formed. Next, after an oxide film is formed on the entire substrate surface, the offset spacer SO is formed by leaving the oxide film on each sidewall of the stack L using the anisotropic etching technique.

Next, ion implantation performed mainly on the NFETs will be described with reference to FIGS. 13A to 13C and FIGS. 14A to 14C.

To improve transistor performance of the NFETs, oblique halo ion implantation using a thin gate insulating film is performed on regions of the P-well Pw1 and the P-well Pw2. First, the resist RE1 is formed on a region excluding the P-well Pw1 and the P-well Pw2 that are the targets of halo ion implantation, that is, on regions of the P-well Pw3 and the N-well Nw. FIGS. 13A to 13C illustrate such a state.

Next, BF₂⁺ ions are obliquely implanted into the substrate surface as indicated by arrows in FIGS. 13A to 13C. Accordingly, BF₂⁺ is implanted into a region around the substrate surface of the P-well Pw1 around the gate G1. Note that BF₂⁺ ions are also implanted into the contact region CO1 in this step.

As illustrated in FIGS. 13A to 13C, BF₂⁺ ions are obliquely implanted into the substrate surface in the halo ion implantation step. In a layout of the comparative example in FIG. 6, the dummy gate GC is arranged around the end portion of the narrow P-well Pw1 in the Y-direction, and thus, there has been concern about generation of arcing. In contrast, in a layout of the present embodiment, no dummy gate GC is arranged around the positions where BF₂⁺ ions are implanted as illustrated in FIG. 13B (e.g., above the STI adjacent to the side of the gate G1 as seen from the contact region CO1 in FIG. 13B, and above the STI adjacent to the side of the N-well NW as seen from the contact region CO1 in FIG. 13A). Thus, generation of arcing due to halo ion implantation can be prevented.

Next, an LDD ion implantation step indicated by arrows in FIGS. 14A to 14C is performed. Namely, following the halo ion implantation illustrated in FIGS. 13A to 13C, LDD ion implantation is performed on NFETs each having a thin gate insulating film. In the LDD ion implantation step, As⁺ ions are implanted perpendicularly to the substrate surface. The ion implantation is performed to implant As⁺ ions into the substrate up to a position shallower than the position in the halo ion implantation as indicated by arrows in FIGS. 14A to 14C. Following the ion implantation, the resist RE1 is detached.

Next, ion implantation performed mainly on the PFETs will be described with reference to FIGS. 15A to 15C and FIGS. 16A to 16C.

To improve transistor performance of the PFETs, oblique halo ion implantation using a thin gate insulating film is performed on a region of the N-well Nw. First, resist RE2 is formed on a region excluding the N-well Nw that is the target of halo ion implantation, that is, on regions of the P-well Pw1 to the P-well Pw3. FIGS. 15A to 15C illustrate such a state.

As⁺ ions are obliquely implanted into the substrate surface as indicated by arrows in FIGS. 15A and 15C. Accordingly, As⁺ is implanted into the substrate surface of the N-well Nw around the gate G2. Note that As⁺ ions are also implanted into the contact regions CO2 and CO3.

For example, even when the dummy gate GC1 is arranged above the STI adjacent to the side of the gate G2 as seen from the contact C03 in FIG. 15C, or above the STI adjacent to the side of the P-well Pw2 as seen from the contact C03 in FIG. 9, arcing is unlikely to occur due to halo ion implantation because a width of the N-well Nw in the X-direction is relatively wide.

Next, an LDD ion implantation step indicated by arrows in FIGS. 16A to 16C is performed. Namely, following the halo ion implantation illustrated in FIGS. 15A to 15C, LDD ion implantation is performed on the PFETs each having a thin gate insulating film. In the LDD ion implantation step, BF₂⁺ ions are implanted perpendicularly to the substrate surface. After the ion implantation, the resist RE2 is detached.

Next, ion implantation performed mainly on an NFET with a thick film will be described with reference to FIGS. 17A to 17C.

An LDD of an NFET with a thick gate insulating film is formed. Resist RE3 is formed on a region excluding the target P-well Pw3, that is, on regions of the P-well Pw1, the P-well Pw2, and the N-well Nw. FIGS. 17A to 17C illustrate such a state.

Next, Phos⁺ ions are implanted as indicated by arrows in FIGS. 17B to 17C. In the LDD ion implantation step, Phos⁺ ions are implanted perpendicularly to the substrate surface. After the ion implantation, the resist RE3 is detached.

Next, ion implantation performed to form sources and drains of for the NFETs, and ion implantation performed on the contact region CO in the N-well Nw will be described with reference to FIGS. 18A to 18C.

To perform ion implantation to form sources and drains, a sidewall SW is formed on each stack L. Namely, after an oxide film is formed on the entire surface, the entire surface is etched back so that the sidewall SW is formed on a side face of the offset spacer SO of each stack L. Next, resist RE4 is formed that does not cover the source or drain region of any of the NFETs or the contact region CO in the N-well Nw. FIGS. 18A to 18C illustrate such a state.

Next, As⁺ ions are implanted as indicated by arrows in FIGS. 18A to 18C. In the ion implantation step, As⁺ ions are implanted perpendicularly to the substrate surface up to a position deeper than the LDD regions. Through the ion implantation, sources and drains of the NFETs are formed, and also, the contact region CO in the N-well Nw is formed. After the ion implantation, the resist RE4 is detached.

Next, ion implantation performed to form sources and drains for the PFETs, and ion implantation performed on the contact region CO in the P-well Pw will be described with reference to FIGS. 19A to 19C.

As illustrated in FIGS. 19A to 19C, resist RE5 is formed that does not cover the source or drain region of any of the PFETs or the contact region CO in the P-well Pw. Next, BF₂⁺ ions are implanted as indicated by arrows in FIGS. 19A and 19C. In the ion implantation step, BF₂⁺ ions are implanted perpendicularly to the substrate surface up to a position deeper than the LDD regions. Through the ion implantation, sources and drains of the PFETs are formed, and also, the contact region CO in the P-well Pw is formed. After the ion implantation, the resist RE5 is detached.

After that, an interlayer film is formed on the entire surface using the CVD method, and a metal to serve as a contact is buried in the interlayer film at a position corresponding to the contact region CO. Then, a wire connected to the contact is patterned.

In this manner, when a CMOS circuit with a halo structure is formed by alternately arranging P-wells and N-wells in a predetermined direction, a dummy gate is not arranged above an STI region around an end portion of a relatively narrow well in a direction orthogonal to the predetermined direction. Accordingly, generation of arcing can be prevented, and a semiconductor device suitable for miniaturization can be provided.

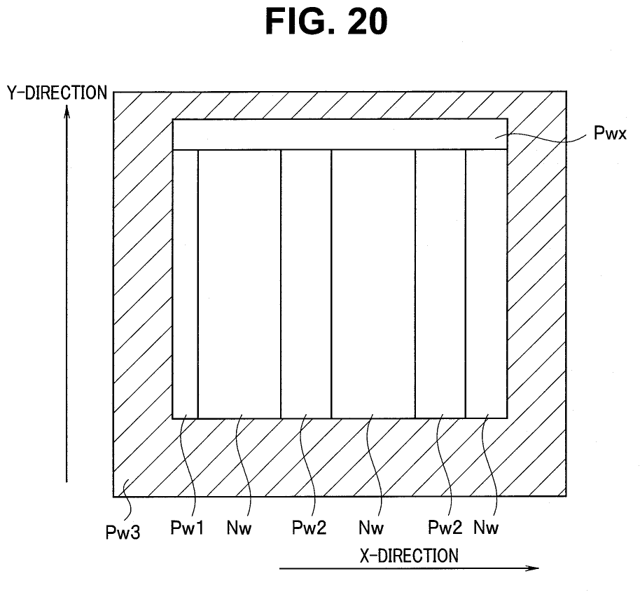

Note that not both ends of each of the P-wells Pw1 and Pw2 in the Y-direction need to be in contact with the P-well Pw3. FIG. 20 is a plan view illustrating an example in which the P-well Pw1 is in contact with the P-well Pw3 on one side in the Y-direction. A P-well Pwx is a region in which an N channel FET (NFET) is formed that has a thin gate insulating film and to which oblique halo ion implantation is applied.

Even in the example of FIG. 20, it is possible to suppress generation of arcing by not arranging the dummy gate GC in one end portion in the Y-direction where resist is present around the P-well Pw1 in three directions.

### Second Embodiment

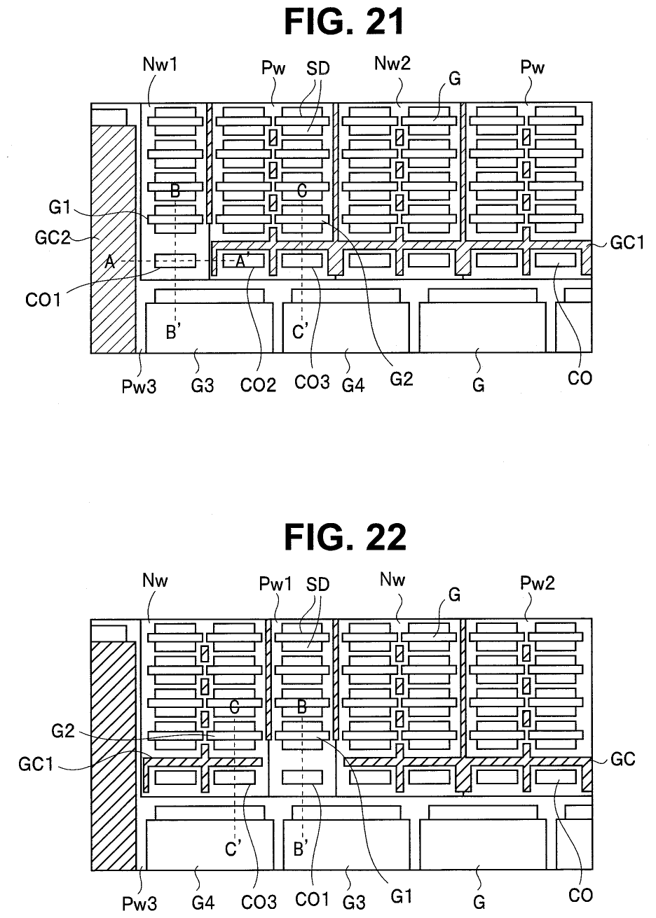

FIG. 21 is a plan view illustrating a second embodiment. In FIG. 21, components identical to the components in FIG. 9 are denoted by identical reference signs, and overlapped description will be omitted.

The first embodiment has described an example in which the P-well Pw1 is formed to have a width smaller than a predetermined threshold (i.e., a predetermined width) in the X-direction, and when oblique halo ion implantation is performed, there is a region where resist REG is present in a relatively nearby position, that is, the resist REG is present around the P-well Pw1 in three directions. In contrast, the present embodiment illustrates an example in which the N-well Nw is formed to have a width smaller than a predetermined threshold in the X-direction, and when oblique halo ion implantation is performed, there is a region where resist REG is present in a relatively nearby position, that is, the resist REG is present around the N-well Nw in three directions.

FIG. 21 illustrates an example of a planar shape of well regions in a transistor formation region provided in a peripheral circuit region. As illustrated in FIG. 21, a P-well Pw3 that is a P-type well region is formed around an N-well Nw1 and an N-well Nw2 that are N-type well regions (hereinafter collectively referred to as N-wells Nw unless there is a need to distinguish between the N-wells) and P-wells Pw that are P-type well regions. The N-wells Nw1 and Nw2 and the P-wells Pw extend in the Y-direction. The N-wells Nw1 and Nw2 and the P-wells Pw are alternately formed in the X-direction.

The N-well Nw1 is a region in which a PFET is formed that has a thin gate insulating film and to which oblique halo ion implantation is applied. The N-well Nw2 has a configuration similar to the configuration of the N-well Nw1, but is wider than the N-well Nw1 in the X-direction. As illustrated in FIG. 21, an N-well contact region CO is formed at an end portion of the N-well Nw1 in the Y-direction. A gate G is formed in a shape extending in the X-direction with respect to diffusion layers forming a source S and a drain D, and PFETs are formed in the N-wells Nw1 and Nw2.

Each P-well Pw is a region in which an NFET is formed that has a thin gate insulating film and to which oblique halo ion implantation is applied. The P-well Pw3 is a region in which an NFET is formed that has a thick gate insulating film and to which oblique halo ion implantation is not applied. Note that the P-well Pw3 is formed to surround the N-wells Nw1 and Nw2 and the P-wells Pw.

In FIG. 21, the N-wells extending in the Y-direction and the P-wells extending in the Y-direction are alternately arranged in the X-direction so that the element arrangement efficiency is improved. Although a CMOS circuit is formed using a pair of an N-well and a P-well, arranging the wells like an N-well-a P-well, a P-well-an N-well, and an N-well-a P-well, . . . can reduce the number of boundaries each existing between an N-well and a P-well that are adjacent to each other.

Dummy gates GC (GC1 and GC2; indicated by shaded portions) are formed above the N-wells Nw and the P-wells Pw. No contact is formed on each dummy gate GC, and thus, the dummy gate GC is in a floating state.

In the present embodiment, no dummy gate GC is arranged at an end portion of the N-well Nw1 in the Y-direction. A width of the N-well Nw1 in the X-direction is smaller than a predetermined width, and thus, the end portion of the N-well Nw1 in the Y-direction is likely to be influenced by neutralizing electrons on the resist REG due to the electron shading effect during oblique halo ion implantation. Thus, the dummy gate GC that would be charged up is not formed at the end portion of the N-well Nw1 in the Y-direction that is likely to be charged up during oblique halo ion implantation. Accordingly, generation of arcing can be prevented in the present embodiment.

Note that in FIG. 21, a dummy gate and contact regions at positions corresponding to line A-A′ are respectively indicated by reference signs GC2, CO1, and CO2, gates and a contact region at positions corresponding to line B-B′ are respectively indicated by reference signs G1, G3, and CO1, and gates, a dummy gate, and a contact region at positions corresponding to line C-C′ are respectively indicated by reference signs G2, G4, GC1, and CO3.

In FIGS. 10 to 19C, replacing the P-well Pw1, the P-well Pw2, and the N-well Nw with the N-well Nw1, the N-well Nw2, and the P-well Pw can indicate a cross-sectional shape corresponding to the planar shape illustrated in FIG. 21. Thus, illustration of drawings and specific description about the cross-section are omitted herein.

The other components and functions are similar to the components and functions of the first embodiment.

In this manner, generation of arcing can also be suppressed in the present embodiment.

### Third Embodiment

FIG. 22 is a plan view illustrating a third embodiment. In FIG. 22, components identical to the components in FIG. 9 are denoted by identical reference signs, and overlapped description will be omitted.

The first embodiment has described an example in which the P-well Pw1, which is formed to have a width smaller than a predetermined threshold in the X-direction, is arranged at a position adjacent to the P-well Pw3 at an end portion in the X-direction. In contrast, the present embodiment illustrates an example in which a P-well Pw, which has a width smaller than a predetermined threshold in the X-direction, is arranged at a position not adjacent to the P-well Pw3 in the X-direction.

In the present embodiment, no dummy gate GC is arranged at an end portion of the P-well Pw1 in the Y-direction, either. A width of the P-well Pw1 in the X-direction is smaller than a predetermined width, and thus, the end portion of the P-well Pw1 in the Y-direction is likely to be influenced by neutralizing electrons on resist REG due to the electron shading effect during oblique halo ion implantation. Thus, the dummy gate GC that would be charged up is not formed at the end portion of the P-well Pw1 in the Y-direction that is likely to be charged up during oblique halo ion implantation. Accordingly, generation of arcing can also be prevented in the present embodiment.

Note that in FIG. 22, gates and a contact region at positions corresponding to line B-B′ are respectively indicated by reference signs G1, G3, and CO1, and gates, a dummy gate, and a contact region at positions corresponding to line C-C′ are respectively indicated by reference signs G2, G4, GC1, and CO3. In such a case, cross-sectional structures cut along lines B-B′ and C-C′ other than a cross-sectional structure cut along line A-A′ of the present embodiment are similar to the corresponding cross-sectional structures in FIGS. 10 to 19C.

The other components and functions are similar to the components and functions of the first embodiment.

As described above, generation of arcing can also be suppressed in the present embodiment.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor device comprising:
N-wells and P-wells extending in a first direction and alternately arranged in a second direction orthogonal to the first direction; and
a dummy gate formed above the N-wells and the P-wells so as to extend across at least one boundary between an N-well and a P-well that are adjacent to each other, the dummy gate being not connected to a wire,
wherein:
the dummy gate is formed in a region other than an end portion in the first direction of, among the N-wells and the P-wells, a well that has a width smaller than a predetermined threshold in the second direction.

2. The semiconductor device according to claim 1, wherein transistors applying oblique halo ion implantation are formed in the N-wells and the P-wells.

3. The semiconductor device according to claim 1, wherein the well that has the width smaller than the predetermined threshold in the second direction is a well arranged at an end portion in the second direction of the N-wells and the P-wells that are alternately arranged in the second direction.

4. The semiconductor device according to claim 1, further comprising a well surrounding the N-wells and the P-wells that are alternately arranged in the second direction.

5. The semiconductor device according to claim 1, wherein a gate insulating film of a transistor formed in a well surrounding the N-wells and the P-wells is thicker than each of gate insulating films of transistors formed in the N-wells and the P-wells.

6. The semiconductor device according to claim 1,
wherein:
transistors applying oblique halo ion implantation are formed in the N-wells and the P-wells, and
the transistors form a logic circuit.

7. The semiconductor device according to claim 6, wherein the logic circuit forms a peripheral circuit, the peripheral circuit being configured to drive memory cells of a NAND nonvolatile memory.

8. The semiconductor device according to claim 1, further comprising an element isolation region formed at each of end portions in the first direction of the N-wells and the P-wells that are alternately arranged in the second direction,
wherein:
the dummy gate is not arranged above the element isolation region at the end portion in the first direction of the well that has the width smaller than the predetermined threshold in the second direction.
